(19) United States
(12) Patent Application Publication
(10) Pub. No.: US 2009/0267698 A1
(43) Pub. Date: Oct. 29, 2009

(54) DUAL SUPPLY INVERTER FOR VOLTAGE CONTROLLED RING OSCILLATOR

(75) Inventor: Chia-Liang Lin, Fremont, CA (US)

Correspondence Address: KNOBBE MARTENS OLSON & BEAR LLP, 2040 MAIN STREET, FOURTEENTH FLOOR, IRVINE, CA, 92614, US

(73) Assignee: REALTEK SEMICONDUCTOR CORP., Hsinchu (TW)

(21) Appl. No.: 12/422,525

(22) Filed: Apr. 13, 2009

Related U.S. Application Data
(60) Provisional application No. 61/048,211, filed on Apr. 27, 2008.

(51) Int. Cl. H03K 3/03

(52) U.S. Cl. 331/57

(57) ABSTRACT

A voltage controlled ring oscillator reduces sensitivity of an oscillation frequency to a control voltage by using a dual supply inverter logic circuit. The dual supply inverter logic circuit includes two inverter circuits coupled in parallel between an input terminal and an output terminal. The first inverter circuit is powered by a variable supply voltage while the second inverter circuit is powered by a substantially fixed supply voltage. The variable supply voltage serves as the control voltage for the voltage controlled ring oscillator and sets the oscillation frequency. The sensitivity of the oscillation frequency to changes in the variable supply voltage is reduced due to the parallel connection of the second inverter circuit powered by a different supply voltage.

The present application claims priority benefits under 35 U.S.C. §119(e) from U.S. Provisional Application No. 61/048,211, filed on Apr. 27, 2008, entitled “Dual Supply Inverter for Voltage Controlled Ring Oscillator,” which is hereby incorporated herein in its entirety by reference.

### BACKGROUND OF THE INVENTION

1. Field of the Invention

The present invention relates to a dual supply inverter logic circuit and in particular to a method and apparatus for using the dual supply inverter logic circuit in a voltage controlled oscillator application.

2. Description of the Related Art

A ring oscillator is widely used to implement a voltage controlled oscillator (VCO). FIG. 1A depicts a 3-stage ring oscillator 100 comprising three inverter stages 101-103 configured in a ring topology. Each inverter stage is powered by a common power supply voltage VDD. Each inverter stage introduces a 180 degrees phase shift, due to its inversion function, plus an additional phase shift due to its circuit delay. In a steady state, an oscillation is sustained when the additional phase shift due to the inverter's circuit delay is equal to 60 degrees. In this case, the respective outputs (V0₁, V0₂, V0₃) from the three inverter stages 101, 102, 103 have identical periodic waveforms of a periodicity of T but are uniformly displaced in time with a spacing of T/3.

FIG. 1B illustrates the output waveforms for the three inverter stages 101, 102, 103 with respect to time. The amount of circuit delay that leads to the additional phase shift of 60 degrees is T/6, since the periodicity T corresponds to a 360 degrees phase shift. An inverter stage is typically embodied by a complementary metal-oxide semiconductor (CMOS) inverter, which is well known to those of ordinary skill in the art and thus not described in detail here. The circuit delay of the inverter is a function of the level of the power supply voltage (e.g., VDD). A higher supply voltage leads to a smaller circuit delay, and therefore a smaller periodicity for the periodic waveform corresponding to a higher frequency. For example, the oscillation frequency of the ring oscillator 100 shown in FIG. 1A can be controlled by adjusting the level of the power supply voltage VDD. This makes the ring oscillator 100 a voltage controlled oscillator.

One drawback to the ring oscillator 100 shown in FIG. 1A is that the oscillator frequency is very sensitive to the level of the control voltage (i.e., VDD). A slight change in the level of the control voltage usually leads to a significant change in the oscillation frequency. For instance, in a design of a 3-stage ring oscillator constructed using a 0.13 μm CMOS process, the oscillation frequencies are 4.80 GHz, 5.46 GHz, and 6.08 GHz, respectively, when the levels of the control voltages are 1.1V, 1.2V, and 1.3V, respectively. Such sensitivity is usually not desirable, since the ring oscillator would be highly susceptible to noise in the control voltage. What is needed is a ring oscillator that is less susceptible to noise in the control voltage.

### SUMMARY OF THE INVENTION

The present invention solves this and other problems by providing a method and an apparatus to reduce sensitivity of a circuit delay in response to a variable voltage. In one embodiment, the sensitivity of a circuit delay to a variable supply voltage is reduced by coupling two similar circuits in parallel. For example, a first circuit and a second circuit having substantially similar transfer functions are coupled in parallel such that the first circuit and the second circuit have respective input nodes commonly connected to an input terminal and respective output nodes commonly connected to an output terminal. That is, the first circuit and the second circuit receives the same input signal at the common input terminal and delivers different respective output signals to the common output terminal. The first circuit is powered by a first supply voltage that is variable to vary a circuit delay of the first circuit. The second circuit is powered by a second supply voltage that is different from the first supply voltage. An overall circuit delay between the input terminal and the output terminal is approximately equal to an average of the circuit delay of the first circuit and a circuit delay of the second circuit.

In one embodiment, the first circuit and the second circuit are implemented with different types of devices or circuit topologies. In another embodiment, the first circuit and the second circuit are implemented with substantially similar devices or circuit topologies such that a sensitivity of the overall circuit delay to variations in the first supply voltage depends on relative device dimensions between the first circuit and the second circuit. For example, when a ratio of device dimensions in the second circuit to corresponding device dimensions in the first circuit is approximately equal to n, the sensitivity of the overall circuit delay to the first supply voltage is reduced by approximately n/(n+1) with respect to a sensitivity of the circuit delay of the first circuit to the first supply voltage.

In one embodiment, the transfer functions of the first circuit and the second circuit are inverting functions. For example, the first circuit and the second circuit combine to form a dual supply inverter logic circuit with reduced sensitivity in circuit delay to a control voltage. The dual supply inverter logic circuit comprises a parallel connection of a first inverter powered by a first supply voltage of a variable level and a second inverter powered by a second power supply of a substantially fixed level. The first inverter and the second inverter share a common input node (or input terminal) and a common output node (or output terminal).

The first supply voltage is the control voltage for the dual supply inverter logic circuit. The first inverter has a first circuit delay that is adjustable (or varies) with the first supply voltage. The second inverter has a second circuit delay that is substantially constant (or fixed) because the second power supply has a substantially fixed voltage level. In one embodiment, the dual supply inverter logic circuit is implemented with complementary metal-oxide semiconductor (CMOS) transistors. For example, the first inverter comprises a first pair of CMOS transistors coupled in series between the first supply voltage and circuit ground while the second inverter comprises a second pair of CMOS transistors coupled in series between the second supply voltage and circuit ground. The sensitivity of a circuit delay between the input terminal and the output terminal of the dual supply inverter logic circuit in response to voltage variations in the first supply voltage is determined by relative device dimensions between the first pair of CMOS transistors and the second pair of CMOS transistors.

In one embodiment, a voltage controlled ring oscillator comprises a plurality of inverter stages configured in a ring topology (e.g., coupled in series and in a closed loop configuration). At least one of the inverter stages is powered by a combination of a first supply voltage of a variable level and a second supply voltage of a substantially fixed level. For example, at least one of the inverter stages comprises a first inverter circuit coupled in parallel with a second inverter circuit. The first inverter circuit and the second inverter circuit have commonly connected input nodes and commonly connected output nodes. The first inverter circuit is configured to be power by the first supply voltage while the second inverter circuit is configured to be powered by the second supply voltage.

The second supply voltage has a substantially fixed voltage potential during normal operation. The first supply voltage has a variable voltage potential that controls an oscillation frequency of an output signal generated by the voltage controlled ring oscillator. For example, increasing the first supply voltage increases the oscillation frequency of the output signal while decreasing the first supply voltage decreases the oscillation frequency of the output signal. Using a combination of the first supply voltage and the second supply voltage reduces a sensitivity of the oscillation frequency to the first supply voltage which serves as a control voltage. For example, the first inverter circuit has a first delay that is dependent on a voltage level of the first supply voltage while the second inverter circuit has a second circuit delay that is dependent on a voltage level of the second supply voltage. The sensitivity of the oscillation frequency to the voltage level of the first supply voltage is dependent on a ratio of the first circuit delay to the second circuit delay.

In one embodiment, the first inverter circuit comprises a first pair of transistors coupled in series between the first supply voltage and a first reference node. Similarly, the second inverter circuit comprises a second pair of transistors coupled in series between the second supply voltage and a second reference node. In one application, the first inverter circuit and the second inverter circuit are implemented in CMOS technology. For example, the first pair of transistors comprises a first P-type field-effect-transistor (P-FET) and a first N-type field-effect-transistor (N-FET) with respective gate terminals coupled to the input node of the first inverter circuit and respective drain terminals coupled to the output node of the first inverter circuit. The second pair of transistors comprises a second P-FET and a second N-FET with respective gate terminals coupled to the input node of the second inverter circuit and respective drain terminals coupled to the output node of the second inverter circuit.

In one embodiment, a pseudo-differential ring oscillator comprises a plurality of pseudo-differential inverter stages coupled serially in a ring configuration with at least one of the pseudo-differential inverter stages comprising a pseudo-differential inverter implemented with two dual supply inverter circuits. The first dual supply inverter circuit is coupled between a positive (or non-inverting) input terminal and a negative (or inverting) output terminal of the pseudo-differential inverter. The second dual supply inverter is coupled between a negative input terminal and a positive output terminal of the pseudo-differential inverter. The pseudo-differential inverter further comprises a latch circuit coupled between the positive output terminal and the negative output terminal. In one embodiment, the latch circuit comprises a pair of cross-coupled NMOS transistors.

In one embodiment, the first dual supply inverter circuit comprises a first sub-circuit coupled in parallel with a second sub-circuit between the positive input terminal and the negative output terminal of the pseudo-differential inverter. The first sub-circuit and the second sub-circuit have substantially similar functions. The first sub-circuit is configured to be powered by a variable supply voltage and the second sub-circuit is configured to be powered by a substantially fixed supply voltage.

The second dual supply inverter circuit comprises a third sub-circuit coupled in parallel with a fourth sub-circuit between the negative input terminal and the positive output terminal of the pseudo-differential inverter. The third sub-circuit is configured to be powered by the variable supply voltage and has a substantially similar circuit topology as the first sub-circuit. The fourth sub-circuit is configured to be powered by the substantially fixed supply voltage and has a substantially similar circuit topology as the second sub-circuit.

The ring oscillators described above can have an even number or an odd number of inverter stages. In the pseudo-differential ring oscillator, pseudo-differential outputs of a last pseudo-differential inverter stage are coupled in an opposite polarity to pseudo-differential inputs of a first pseudo-differential inverter stage. However, each of the pseudo-differential inverter stages between the first pseudo-differential stage and the last pseudo-differential inverter have pseudo-differential inputs coupled to pseudo-differential outputs of a previous stage and pseudo-differential outputs coupled to pseudo-differential inputs of a next stage in the same polarity.

For purposes of summarizing the invention, certain aspects, advantages, and novel features of the invention have been described herein. It is to be understood that not necessarily all such advantages may be achieved in accordance with any particular embodiment of the invention. Thus, the invention may be embodied or carried out in a manner that achieves or optimizes one advantage or group of advantages as taught herein without necessarily achieving other advantages as may be taught or suggested herein.

### BRIEF DESCRIPTION OF THE DRAWINGS

A general architecture that implements the various features of the invention will now be described with reference to the drawings. The drawings and the associated descriptions are provided to illustrate embodiments of the invention and not to limit the scope of the invention. Throughout the drawings, reference numbers are re-used to indicate correspondence between referenced elements.

FIG. 1A is a block diagram of a 3-stage ring oscillator according to the prior art.

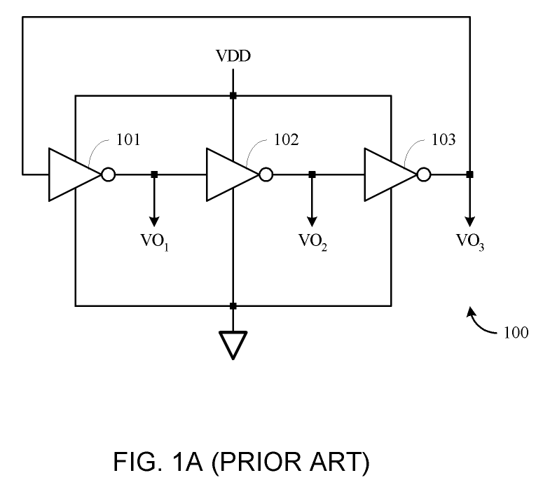

FIG. 1B illustrates output voltages with respect to time for the different stages in the 3-stage ring oscillator of FIG. 1A.

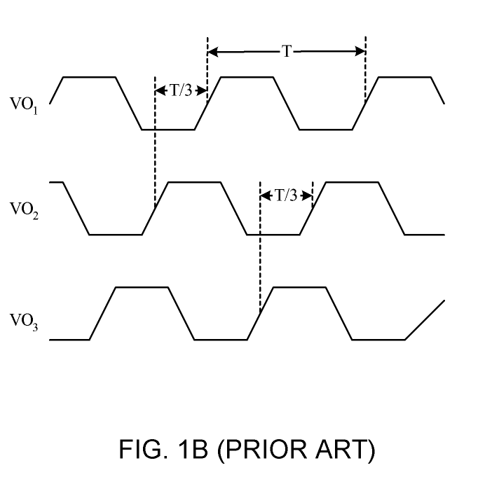

FIG. 2 is a block diagram of a dual supply inverter in accordance with one embodiment of the present invention.

FIG. 3A is a block diagram of one embodiment of a ring oscillator implemented with a plurality of dual supply inverters.

FIG. 3B is a schematic diagram of one embodiment of a ring oscillator implemented with dual supply inverters.

FIG. 4A is a block diagram of one embodiment of a pseudo-differential dual supply inverter.

FIG. 4B is a schematic diagram of one embodiment of a latch circuit used in the pseudo-differential dual supply inverter.

FIG. 5A is a block diagram of one embodiment of a ring oscillator implemented with at least one pseudo-differential dual supply inverter.

FIG. 5B is a schematic diagram of one embodiment of a ring oscillator implemented with pseudo-differential dual supply inverters.

### DETAILED DESCRIPTION OF THE INVENTION

The present invention relates to a method and an apparatus to reduce sensitivity of a circuit delay in response to a variable voltage. While the specification describes several example embodiments of the invention, it should be understood that the invention can be implemented in many way and is not limited to the particular examples described below or to the particular manner in which any features of such examples are implemented.

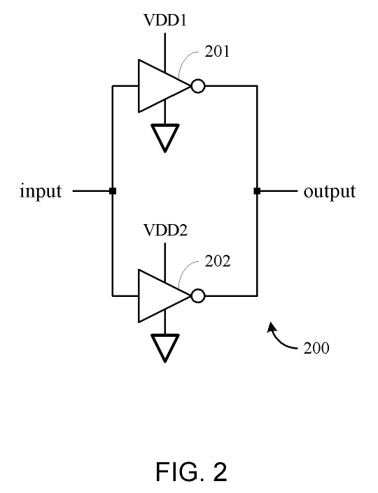

FIG. 2 is a block diagram of a dual supply inverter 200 in accordance with one embodiment of the present invention. The dual supply inverter 200 comprises a first inverter logic circuit 201 and a second inverter logic circuit 202 configured in a parallel topology. That is, the first inverter logic circuit 201 is coupled in parallel with the second inverter logic circuit 202 such that they share a common input terminal (input) and a common output terminal (output). The first inverter logic circuit 201 receives power from a first supply voltage (VDD1), while the second inverter logic circuit 202 receives power from a second supply voltage (VDD2). The first supply voltage is adjustable and serves as a control voltage in some applications. The second supply voltage is substantially fixed.

If the first inverter logic circuit 201 and the second inverter logic circuit 202 do not share the common output terminal, the first inverter logic circuit 201 and the second inverter 202 have independent circuit delays. The first inverter logic circuit 201 has a first circuit delay that is dependent on the level of the first supply voltage and device dimensions in the first inverter logic circuit 201. For example, varying the first supply voltage varies the first circuit delay. The second inverter logic circuit 202 has a second circuit delay that is dependent on the level of the second supply voltage and device dimensions in the second inverter logic circuit 202. For example, the second circuit delay is substantially constant when the second supply voltage is substantially fixed. When the first inverter logic circuit 201 and the second inverter logic circuit 202 are coupled in the parallel between the common input terminal and the common output terminal, an overall circuit delay between the common input terminal and the common output terminal of the dual supply inverter 200 is somewhere between the first circuit delay and the second circuit delay.

In one embodiment, the first inverter logic circuit 201 and the second inverter logic circuit 202 are implemented with substantially identical devices and the overall circuit delay is approximately an average of the first circuit delay and the second circuit delay. In this case, varying the first supply voltage varies the overall circuit delay, but the sensitivity of the overall circuit delay to the first supply voltage is approximately half of the sensitivity of the first circuit delay to the first supply voltage. That is, the sensitivity of the overall circuit delay to variations in the first supply voltage (or control voltage) is reduced by keeping the second supply voltage substantially constant.

A degree of reduction in the sensitivity of the overall circuit delay to the first supply voltage is dependent on a relative strength between the first inverter logic circuit 201 and the second inverter logic circuit 202. If the two inverter logic circuits 201, 202 have approximately equal strengths (e.g., are substantially identical circuits), the reduction in sensitivity is approximately 50% (e.g., 1/(1+1)=0.5). If the second inverter logic circuit 202 is three times higher in strength than the first inverter logic circuit 201, the reduction in sensitivity is approximately 75% (e.g., 3/(3+1)=0.75).

The strength of a CMOS inverter is determined by dimensions of its internal PMOS and NMOS devices. The relative strength, therefore, can be determined by relative device dimensions. Circuit designers thus have freedom in controlling the degree of reduction in the sensitivity by properly choosing a relative strength or device dimensions. For example, if a ratio of device dimensions in the second inverter logic circuit 202 to corresponding device dimensions in the first inverter logic circuit 201 is approximately equal to n, the sensitivity of the overall circuit delay between the input terminal and the output terminal to the first supply voltage is reduced by approximately n/(n+1) with respect to the sensitivity of the first circuit delay to the first supply voltage.

By way of example, the embodiment in FIG. 2 shows inverting logic functions but other circuit functions are possible. In other words, sensitivity of an overall circuit delay for any circuit function in response to a variable supply voltage can be reduced by coupling two circuits in parallel and powering the two circuits with different supply voltages. A first circuit having a first transfer function is powered by the variable supply voltage while a second circuit having a second transfer function is powered by a different supply voltage that is independent of the variable supply voltage. The first circuit has a first circuit delay that varies with the variable supply voltage. The second circuit has a second circuit delay that is not affected by the variable supply voltage. The first circuit and the second circuit can be implemented with different types of devices, but the second transfer function is substantially similar to the first transfer function. The first circuit and the second circuit have respective input nodes commonly connected to an input terminal and respective output nodes commonly connected to an output terminal. The overall circuit delay between the input terminal and the output terminal is approximately equal to an average of the first circuit delay and the second circuit delay.

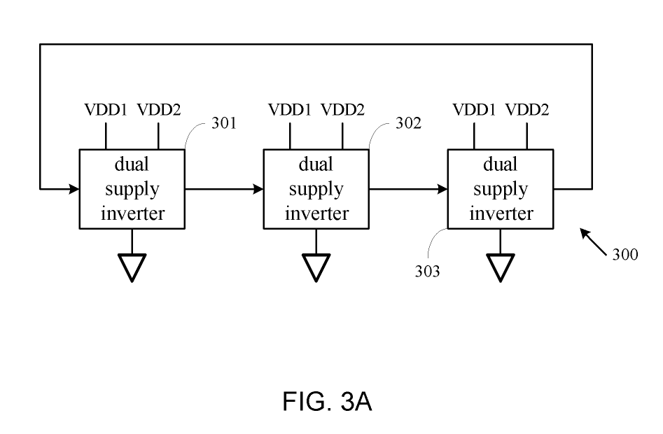

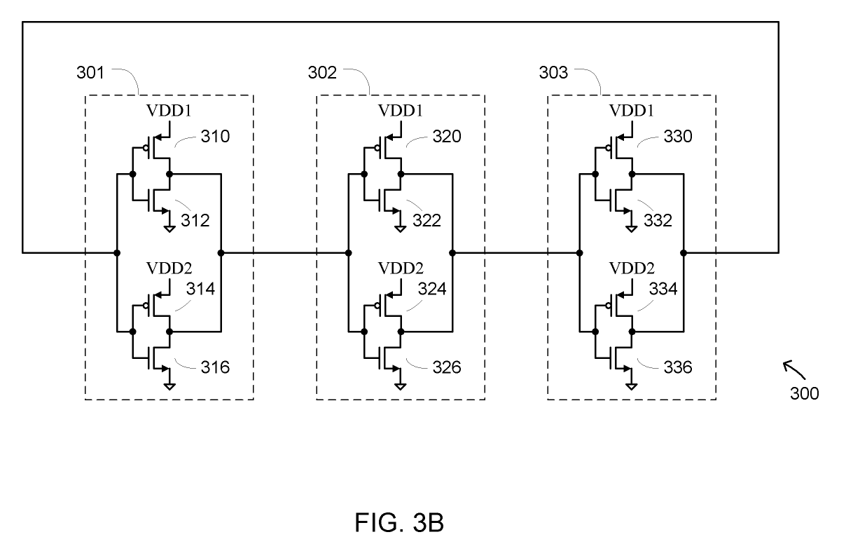

FIG. 3A illustrates one embodiment of a ring oscillator 300 that uses one or more dual supply inverters to reduce sensitivity of an oscillation frequency to variations in a control voltage (e.g., a power supply voltage). The ring oscillator 300 shown in FIG. 3A comprises three dual supply inverter stages 301-303 configured in a ring topology (e.g., coupled in series and in a closed loop). Each of the dual supply inverter stages 301-303 receives a first supply voltage VDD1 of a variable level and a second supply voltage VDD2 of a substantially fixed level. Each of the dual supply inverter stages 301-303 can be implemented by a circuit that is substantially similar to the dual supply inverter 200 described above with respect to FIG. 2.

During normal operation, the second supply voltage VDD2 has a substantially fixed voltage level while the first supply voltage VDD1 has a voltage level that varies and functions as a control voltage for the ring oscillator 300. For example, varying the voltage level of the first supply voltage VDD1 varies circuit delays of the respective dual supply inverter stages 301-303 and therefore controls an oscillation frequency of an output signal generated by the ring oscillator 300. The output signal can be provided by an output from any one of the dual supply inverter stages 301-303. As discussed above, sensitivity of the circuit delay for the dual supply inverter 200 in response to the first supply voltage VDD1 (or control voltage) can be controlled or reduced by design. Thus, sensitivity of the oscillation frequency in the ring oscillator 300 in response to the first supply voltage can be similarly controlled or reduced by design.

FIG. 3B is a schematic diagram of one embodiment of the ring oscillator 300 implemented in CMOS technology. Each of the dual supply inverter stages 301-303 is implemented in a similar manner with two inverter circuits coupled in parallel and each inverter circuit comprising CMOS transistors arranged in substantially similar circuit topologies. For example, the first dual supply inverter stage 301 comprises a first inverter circuit implemented with a first pair of transistors 310, 312 and a second inverter circuit implemented with a second pair of transistors 314, 316. The first pair of transistors 310, 312 is coupled in series between the first supply voltage VDD1 and a first reference node (e.g., circuit ground). In particular, the first pair of transistors 310, 312 includes a first P-FET 310 and a first N-FET 312 with respective gate terminals coupled to an input node of the first inverter circuit and respective drain terminals coupled to an output node of the first inverter circuit. The first P-FET 310 has a source terminal coupled to the first supply voltage VDD1 while the first N-FET 312 has a source terminal coupled to circuit ground.

The second pair of transistors 314, 316 is coupled in series between the second supply voltage VDD2 and a second reference node (e.g., circuit ground). In particular, the second pair of transistors 314, 316 includes a second P-FET 314 and a second N-FET 316 with respective gate terminals coupled to an input node of the second inverter circuit and respective drain terminals coupled to an output node of the second inverter circuit. The second P-FET 314 has a source terminal coupled to the second supply voltage VDD2 while the second N-FET 316 has a source terminal coupled to circuit ground. The input node of the first inverter circuit and the input node of the second inverter circuit are commonly connected to an input terminal of the first dual supply inverter stage 301. The output node of the first inverter circuit and the output node of the second inverter circuit are commonly connected to an output terminal of the first dual supply inverter stage 301.

If the first inverter circuit and the second inverter circuit were not commonly connected at the output terminal, the first inverter circuit would have a first circuit delay that is dependent on (or controlled by) the first supply voltage VDD1 while the second inverter circuit would have a second circuit delay that is controlled by the second supply voltage VDD2. When the first inverter circuit and the second inverter circuit are commonly connected at the output terminal as shown in FIG. 3B, an overall circuit delay between the input terminal and the output terminal of the first dual supply inverter stage 301 is approximately equal to an average of the first circuit delay and the second circuit delay. As discussed above, the oscillation frequency of the ring oscillator 300 can be adjusted by varying the overall circuit delay. For example, the oscillation frequency can be increased by increasing the voltage level of the first supply voltage VDD1 or decreased by decreasing the voltage level of the first supply voltage VDD1.

The degree of sensitivity of the oscillation frequency to the voltage level of the first supply voltage VDD1 is dependent on a ratio of the first circuit delay to the second circuit delay. The first circuit delay and the second circuit delay are also dependent on respective device dimensions of the first inverter circuit and the second inverter circuit. Thus, the sensitivity of the overall circuit delay and oscillation frequency to the first supply voltage VDD1 can be controlled by setting relative device dimensions between the first inverter circuit and the second inverter circuit.

The principle of the present invention can be practiced in many alternative embodiments without departing from the scope of the present invention. The number of inverter stages is not limited to three as shown in the ring oscillator 300 of FIGS. 3A and 3B. Different numbers of inverter stages are also possible. For example, the number of inverter stages can be any odd integer greater than one when signals between inverter stages are transmitted in a single-ended configuration and can be any integer greater than one when signals between inverter stages are transmitted in a differential or pseudo-differential configuration.

In addition, it is not necessary to use a dual supply inverter for every inverter stage of the ring oscillator 300. Some of the inverter stages in the ring oscillator 300 can be implemented by prior art inverters rather than a dual supply inverter. For example, at least one inverter stage in the ring oscillator 300 is implemented by a dual supply inverter similar to the dual supply inverter 200 described above while remaining inverter stages can be implemented by inverter circuits having a different circuit topology or that are powered by only the first supply voltage VDD1, only the second supply voltage VDD2, or another supply voltage that is different from the first supply voltage or the second supply voltage.

Furthermore, the inverter circuits within a dual supply inverter do not need to be substantially identical. For example, the inverter circuit coupled to the first supply voltage VDD1 can have a different circuit topology or be implemented in a different technology than the inverter circuit coupled to the second supply voltage VDD2. The inverter circuits are also not limited to a CMOS implementation. For example, one or both of the inverter circuits can be implemented using bipolar transistors.

Finally, the dual supply inverter is not limited to two inverter circuits and two supply voltages. The dual supply inverter can have one or more additional inverter circuits coupled between its input terminal and output terminal in a parallel configuration with the other inverter circuits. Each additional inverter circuit can be powered by the first supply voltage VDD1, the second supply voltage VDD2, an additional supply voltage having a variable voltage level like the first supply voltage VDD1, or an additional supply voltage having a substantially constant level like the second supply voltage VDD2.

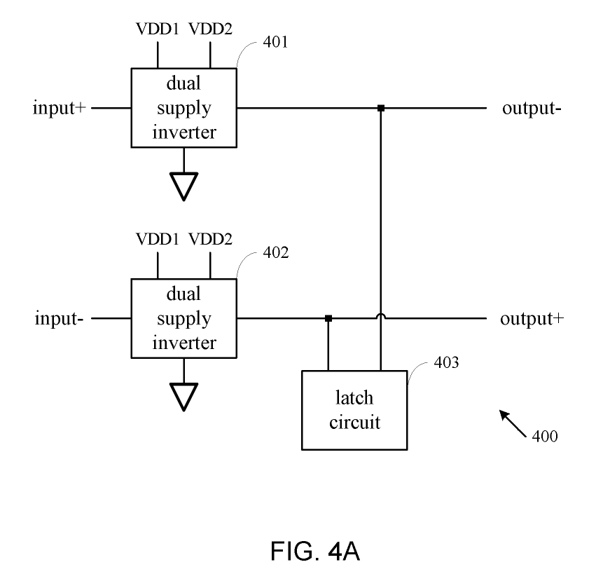

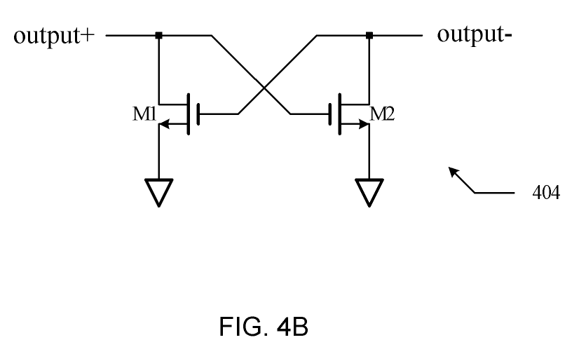

FIG. 4A illustrates one embodiment of a dual supply inverter stage 400 arranged in a pseudo-differential topology. The dual supply inverter stage 400 includes a positive input terminal (input+), a negative input terminal (input−), a positive output terminal (output+), and a negative output terminal (output−). A first dual supply inverter 401 is coupled between the positive input terminal and the negative output terminal of the dual supply inverter stage 400. A second dual supply inverter 402 is coupled between the negative input terminal and the positive output terminal of the dual supply inverter stage 400. A latch circuit 403 is coupled between the positive output terminal and the negative output terminal.

The first dual supply inverter 401 comprises a first sub-circuit coupled in parallel with a second sub-circuit between the positive input terminal and the negative output terminal. The first sub-circuit and the second sub-circuit have substantially similar functions but the first sub-circuit is configured to be powered by a variable supply voltage while the second sub-circuit is configured to be powered by a substantially fixed supply voltage. The second dual supply inverter 401 comprises a third sub-circuit coupled in parallel with a fourth sub-circuit between the negative input terminal and the positive output terminal. The third sub-circuit is configured to be powered by the variable supply voltage and has a substantially similar circuit topology as the first sub-circuit. The fourth sub-circuit is configured to be powered by the substantially fixed supply voltage and has a substantially similar circuit topology as the second sub-circuit. In one embodiment, the first dual supply inverter 401 and the second dual supply inverter 402 are substantially similar to the dual supply inverter described above with respect to FIG. 2, 3A or 3B.

FIG. 4B shows one implementation for the latch circuit 403. For example, a latch circuit 404 shown in FIG. 4B comprises a pair of NMOS transistors (M1, M2) cross-coupled between the positive output terminal and the negative output terminal of the dual supply inverter stage 400. The principle of the latch circuit 404 is well known to those of ordinary skill in the art and is thus not described in further detail. Other implementations for the latch 403 are also possible.

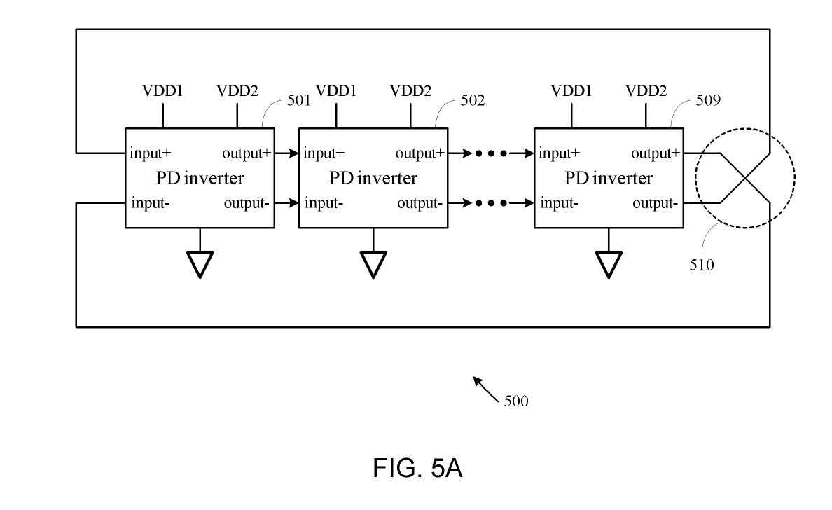

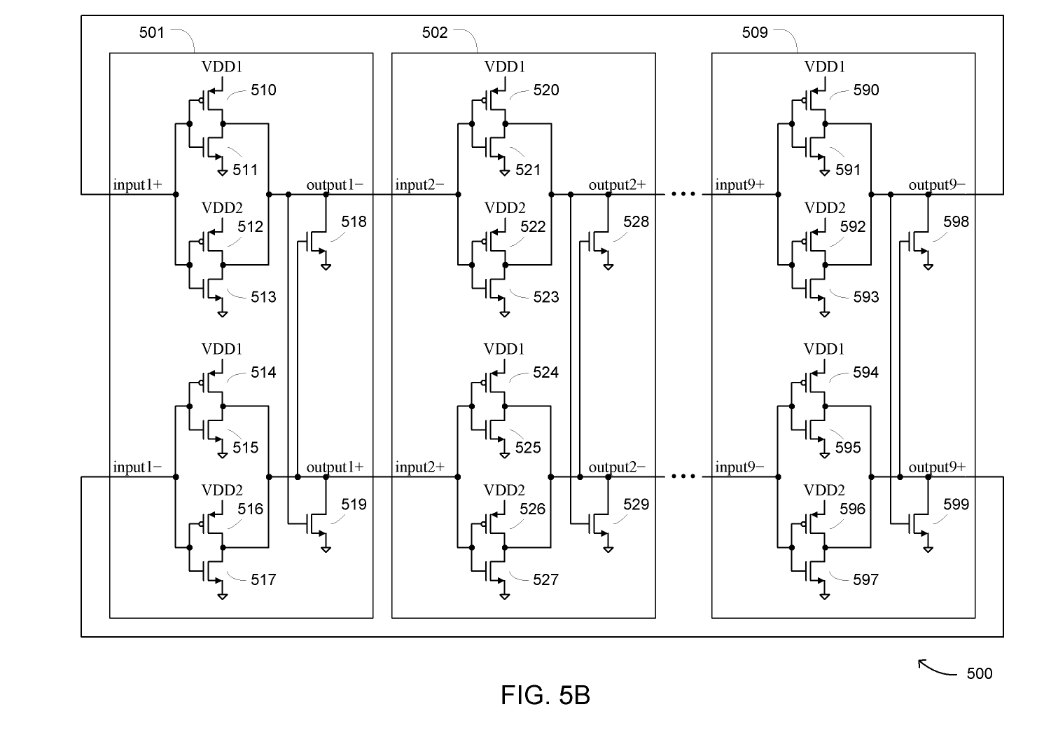

FIG. 5A is a block diagram of one embodiment of a pseudo-differential ring oscillator 500 implemented with a plurality of pseudo-differential inverter stages 501-509, including a first pseudo-differential inverter stage 501 and a last pseudo-differential inverter stage 509 configured in a ring topology. Each of the pseudo-differential inverter stages between the first pseudo-differential stage 501 and the last pseudo-differential inverter 509 have pseudo-differential inputs coupled to pseudo-differential outputs of a previous stage and pseudo-differential outputs coupled to pseudo-differential inputs of a next stage in the same polarity. However, the pseudo-differential ring oscillator 500 includes a polarity inversion 510 between outputs of the last pseudo-differential inverter stage 509 and inputs of the first pseudo-differential inverter stage 501. That is, the pseudo-differential outputs of the last pseudo-differential inverter stage 509 are coupled in an opposite polarity to the pseudo-differential inputs of the first pseudo-differential inverter stage 501.

At least one of the pseudo-differential inverter stages 501-509 is a pseudo-differential dual supply inverter stage similar to the dual supply inverter stage 400 described above. By way of example, the pseudo-differential ring oscillator 500 shows all of the pseudo-differential inverter stages 501-509 as pseudo-differential dual supply inverter stages. In particular, each of the pseudo-differential inverter stages 501-509 is powered by a combination of a first power supply (VDD1) of a variable level and a second power supply (VDD2) of a substantially fixed level. FIG. 5B illustrates an example implementation of the pseudo-differential ring oscillator 500 in CMOS technology.

It is not necessary to use a pseudo-differential dual supply inverter for every stage in the pseudo-differential ring oscillator 500. In some embodiments, some of the pseudo-differential inverter stages 501-509 can be pseudo-differential single supply inverter stages. A pseudo-differential single supply inverter stage can be similar to the dual supply inverter stage 400 shown in FIG. 4A except the first dual supply inverter 401 and the second dual supply inverter 402 are replaced by two single-ended inverters powered by either a variable power supply or a substantially fixed power supply.

A pseudo-differential ring oscillator can have any integer number of inverter stages greater than one. For example, the pseudo-differential ring oscillator 500 can be reduced to a 2-stage pseudo-differential ring oscillator by eliminating the pseudo-differential inverter stages between the first pseudo-differential inverter stage 501 and the last pseudo-differential inverter stage 509 such that the last pseudo-differential inverter stage 509 directly follows the first pseudo-differential inverter stage 501. The number of stages in the pseudo-differential ring oscillator 500 can also be increased by inserting additional pseudo-differential inverter stages between the first pseudo-differential inverter stage 501 and the last pseudo-differential inverter stage 509.

As discussed above, the present invention is not limited to inverter circuits. Other circuit functions can be implemented such that sensitivity of an overall circuit delay to a variable supply voltage is reduced by coupling a first circuit powered by the variable supply voltage in parallel with a second circuit powered by a substantially fixed supply voltage. The first circuit and the second circuit provide similar circuit functions. The first circuit and the second circuit also share a common input node and a common output node.

While certain embodiments of the inventions have been described, these embodiments have been presented by way of example only, and are not intended to limit the scope of the inventions. Indeed, the novel methods and devices described herein may be embodied in a variety of other forms; furthermore, various omissions, substitutions, and changes in the form of the methods and devices described herein may be made without departing from the spirit of the inventions. The accompanying claims and their equivalents are intended to cover such forms or modifications as would fall within the scope and spirit of the inventions.

What is claimed is:

1. A voltage controlled ring oscillator comprising a plurality of inverter stages coupled in series and in a closed loop configuration, wherein at least one of the inverter stages comprises a first inverter circuit coupled in parallel with a second inverter circuit, the first inverter circuit and the second inverter circuit have commonly connected input nodes and commonly connected output nodes, the first inverter circuit is configured to be powered by a first supply voltage while the second inverter circuit is configured to be powered by a second supply voltage, the second supply voltage has a substantially fixed voltage potential during normal operation, and the first supply voltage has a variable voltage potential that controls an oscillation frequency of an output signal generated by the voltage controlled ring oscillator.

2. The voltage controlled ring oscillator of claim 1, wherein the first inverter circuit comprises a first pair of transistors coupled in series between the first supply voltage and a first reference node, and the second inverter circuit comprises a second pair of transistors coupled in series between the second supply voltage and a second reference node.

3. The voltage controlled ring oscillator of claim 2, wherein the first inverter circuit and the second inverter circuit are implemented in CMOS technology, the first pair of transistors comprises a first P-FET and a first N-FET with respective gate terminals coupled to the input node of the first inverter circuit and respective drain terminals coupled to the output node of the first inverter circuit, and the second pair of transistors comprises a second P-FET and a second N-FET with respective gate terminals coupled to the input node of the second inverter circuit and respective drain terminals coupled to the output node of the second inverter circuit.

4. The voltage controlled ring oscillator of claim 1, wherein increasing the first supply voltage increases the oscillation frequency of the output signal.

5. The voltage controlled ring oscillator of claim 1, wherein the first inverter circuit has a first circuit delay that is dependent on a voltage level of the first supply voltage, the second inverter circuit has a second circuit delay that is dependent on a voltage level of the second supply voltage, and a sensitivity of the oscillation frequency to the voltage level of the first supply voltage is dependent on a ratio of the first circuit delay to the second circuit delay.

6. A method to reduce sensitivity of a circuit delay in response to a variable supply voltage, the method comprising:
providing a first circuit having a first transfer function;
coupling a second circuit in parallel with the first circuit such that the first circuit and the second circuit have respective input nodes commonly connected to an input terminal and respective output nodes commonly connected to an output terminal, wherein the second circuit has a second transfer function that is substantially similar to the first transfer function;
powering the first circuit with a first supply voltage, wherein the first supply voltage is variable to vary a circuit delay of the first circuit; and
powering the second circuit with a second supply voltage, wherein the second supply voltage is different from the first supply voltage.

7. The method of claim 6, wherein an overall circuit delay between the input terminal and the output terminal is approximately equal to an average of the circuit delay of the first circuit and a circuit delay of the second circuit.

8. The method of claim 7, wherein the first circuit and the second circuit are implemented with substantially similar circuit topologies, and a sensitivity of the overall circuit delay to variations in the first supply voltage depends on relative device dimensions between the first circuit and the second circuit.

9. The method of claim 6, wherein the first circuit and the second circuit are implemented with substantially similar devices, a ratio of device dimensions in the second circuit to corresponding device dimensions in the first circuit is approximately equal to n, and a sensitivity of a circuit delay between the input terminal and the output terminal to the first supply voltage is reduced by approximately n/(n+1) with respect to a sensitivity of the circuit delay of the first circuit to the first supply voltage.

10. The method of claim 6, wherein the first circuit and the second circuit are implemented with different types of devices.

11. The method of claim 6, wherein the first circuit and the second circuit are implement with complementary metal-oxide semiconductor transistors arranged in substantially similar circuit topologies.

12. The method of claim 6, wherein first transfer function and second transfer function are inverting functions.

13. The method of claim 12, wherein a combination of the first circuit and the second circuit forms one of a plurality of inverter stages in a ring oscillator, and the first supply voltage controls a frequency of oscillation for an output signal of the ring oscillator.

14. A dual supply inverter comprising:
a first inverter circuit coupled between an input terminal and an output terminal, wherein the first inverter circuit is powered by a first supply voltage that is adjustable to adjust a circuit delay of the first inverter circuit; and
a second inverter circuit coupled in parallel with the first inverter circuit between the input terminal and the output terminal, wherein the second inverter circuit is powered by a second supply voltage that is substantially constant such that a circuit delay of the second inverter circuit is substantially fixed.

15. The dual supply inverter of claim 14, wherein the first inverter circuit comprises a first pair of CMOS transistors coupled in series between the first supply voltage and circuit ground while the second inverter circuit comprises a second pair of CMOS transistors coupled in series between the second supply voltage and circuit ground.

16. The dual supply inverter of claim 14, wherein the first inverter circuit and the second inverter circuit are implemented with substantially similar types of devices, and a sensitivity of a circuit delay between the input terminal and the output terminal in response to voltage variations in the first supply voltage is determined by relative device dimensions between the first inverter circuit and the second inverter circuit.

17. A pseudo-differential ring oscillator comprising a plurality of pseudo-differential inverter stages coupled serially in a ring configuration, wherein at least one of the pseudo-differential inverter stages comprises a pseudo-differential inverter further comprising:
a first dual supply inverter circuit coupled between a positive input terminal and a negative output terminal of the pseudo-differential inverter, wherein the first dual supply inverter comprises a first sub-circuit coupled in parallel with a second sub-circuit between the positive input terminal and the negative output terminal of the pseudo-differential inverter, the first sub-circuit and the second sub-circuit have substantially similar functions, the first sub-circuit is configured to be powered by a variable supply voltage, and the second sub-circuit is configured to be powered by a substantially fixed supply voltage;
a second dual supply inverter circuit coupled between a negative input terminal and a positive output terminal of the pseudo-differential inverter, wherein the second dual supply inverter comprises a third sub-circuit coupled in parallel with a fourth sub-circuit between the negative input terminal and the positive output terminal of the pseudo-differential inverter, the third sub-circuit is configured to be powered by the variable supply voltage and has a substantially similar circuit topology as the first sub-circuit, and the fourth sub-circuit is configured to be powered by the substantially fixed supply voltage and has a substantially similar circuit topology as the second sub-circuit; and
a latch circuit coupled between the positive output terminal and the negative output terminal.

18. The pseudo-differential ring oscillator of claim 17, wherein the latch circuit comprises a pair of crossed-coupled NMOS transistors.

19. The pseudo-differential ring oscillator of claim 17, wherein pseudo-differential outputs of a last pseudo-differential inverter stage are coupled in an opposite polarity to pseudo-differential inputs of a first pseudo-differential inverter stage.
